(19) United States
(12) Patent Application Publication
(10) Pub. No.: US 2012/0025177 A1
(43) Pub. Date: Feb. 2, 2012

(54) Phosphorescent light-emitting iridium complex containing pyridyltriazole ligand

(75) Inventors: Ung Chan Yoon, Busan (KR); Hea Jung Park, Busan (KR); Dae Won Cho, Busan (KR); Jung Hei Choi, Busan (KR)

(73) Assignee: SOLVAY SA, Brussels (BE)

(21) Appl. No.: 13/147,876

(22) PCT Filed: Feb. 6, 2009
(86) PCT No.: PCT/KR2009/000590

§ 371 Date: Aug. 4, 2011

(51) Int. Cl. H01L 51/54; C07F 15/00

(52) U.S. Cl. 257/40; 546/4; 257/E51.024

(57) ABSTRACT

An Ir complex having a pyridyl triazole ligand substituted with at least one substituent on its pyridyl ring, and a light emitting material comprising such Ir complex. Such light emitting material was found to have a significantly enhanced photophosphorescence quantum yield and hypsochromic blue shifted photophosphorescent emission over other Ir complexes with a pyridyl triazole ligand having no substituent in its pyridine ring. Use of such light emitting material and an organic light emitting device including the same.

### TECHNICAL FIELD

The present invention relates to a light-emitting material and its use, as well as a light-emitting device capable of converting electrical energy into light.

### BACKGROUND ART

Recently, various display devices have been actively researched and developed, particularly those based on electroluminescence from organic materials.

Although many organic materials exhibit fluorescence (i.e., luminescence from a symmetry-allowed process) from singlet excitons, there is only few materials exhibit phosphorescence efficiently at room temperature. If phosphorescent materials are successfully utilized, then they can produce enormous benefits for organic electroluminescent devices especially in efficiencies. For example, the advantage of utilizing phosphorescent materials is that all singlet and triplet excitons (formed by combining holes and electrons in an EL), which are, in part, triplet-based in phosphorescent devices, may participate in the energy transfer and luminescence. This can be achieved by phosphorescence emission itself. Alternatively, it can be accomplished by using phosphorescent materials to improve the efficiency of fluorescence process as a phosphorescent host or a dopant in a fluorescent guest, with phosphorescence from a triplet state of the host enabling energy transfer from a triplet state of the host to a singlet state of the guest.

As a candidate for blue emissive material, there has been reported a light-emitting device utilizing the emission from an iridium complex having a phenylpyridine and picolinic acid ligands (e.g., iridium(III)bis[(4,6-difluorophenyl)pyridinato-N,C2′]picolinate), which are standard complexes for blue-light emission. Further, other types of heterocycles containing nitrogen have been also studied.

U.S. Pat. No. 7,329,898 B2 discloses various Ir complexes having phenylpyridine and heterocyclic ligands, which can emit a light of blue, white, etc. with high luminance and light-emitting efficiency as well as low minimum driving voltage and excel durability. Japanese Patent Publication No. 2008143826 A discloses Pt complexes having nitrogen-containing cycloplatinated ligands, e.g., dimethylbis(2-phenylpyridine)Pt(IV) and organic electroluminescent devices having emitter layers containing the complexes, which emit blue light with high luminescence efficiency and long service life. A OLED device manufactured using one Pt complex, dimethylbis(2-phenylpyridine)Pt(IV), exhibits luminescence peaks at 449, 478 and 507 nm, as well as luminescence quantum yield of 0.16 (in CH₂Cl₂).

U.S. Patent Application Publication No. US20080217606 A1 discloses organic light-emitting diodes, which employ iridium complexes with triazole, imidazole or pyrazole derivative ligands in their electroluminescent layers.

In addition to the above patents, some literatures [Yeh, Shi-Jay et al., “New Dopant and Host Materials for Blue-Light-Emitting Phosphorescent Organic Electroluminescent Devices,” Advanced Materials (Weinheim, Germany) 17(3): 285-289 (2005); Shin-ya Takizawa et al., “Finely-tuned Blue-phosphorescent Iridium Complexes Based on 2-Phenylpyridine Derivatives and Application to Polymer Organic Light-emitting Device,” Chemistry Letters 35(7) 748-749; Enrico Orselli et al., “Blue-Emitting Iridium Complexes with Substituted 1,2,4-Triazole Ligands: Synthesis, Photophysics, and Devices,” Inorg. Chem., 46(26): 11082-11093 (2007); and Zhang Xiuju, “Synthesis and Phosphorescence of a New Greenish-blue Light-emitting Iridium (III) Bis(1-phenylpyridine)(1,2,4-triazole Pyridine),” LED Journal, 28(1): 44-48(2007/02)] disclose Ir complexes having an unsubstituted or 5-substituted triazole ligand.

### DISCLOSURE

### Technical Problem

However, the above light-emitting materials do not exhibit sufficient luminescent efficiency at the blue region. Thus, there is a need to develop iridium complexes exhibiting high external quantum efficiencies and luminance compared to the standard complexes used while emitting blue light.

### Technical Solution

It is thus an object of the present invention to provide an Ir complex represented by formula (I):

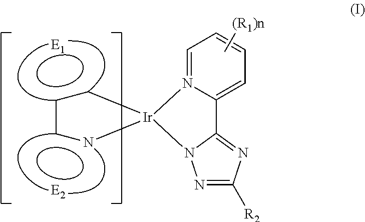

wherein:

E₁ represents an aromatic or heteroaromatic ring optionally condensed with additional aromatic moieties or non-aromatic cycles, said ring optionally having one or more substituents optionally forming a condensed structure with a ring comprising E₂, said ring coordinating to the metal M via a sp² hybridized carbon;

E₂ represents a N-containing aromatic ring optionally condensed with additional aromatic moieties or non-aromatic cycles, said ring optionally having one or more substituents optionally forming a condensed structure with the ring comprising E₁, said ring coordinating to the metal M via a sp² hybridized nitrogen;

R₁ is an electron-donating group, which is same or different at each occurrence and is independently selected from —F, —Cl, —Br, a straight or branched C₁₋₂₀ alkyl, a C₃₋₂₀ cyclic alkyl, a straight or branched C₁₋₂₀ alkoxy, a C₁₋₂₀ dialkylamino, a C₄₋₁₄ aryl, a C₄₋₁₄ heteroaryl which may be substituted by one or more non-aromatic radicals; and a plurality of substituents R₁ either on the same ring or on two different rings forming a further mono- or polycyclic ring system which is optionally aromatic;

R₂ is an electron-withdrawing group, which is selected from —F, —CN, —NO₂, (per)fluoroalkyl, (per)fluoroaryl, (per)fluororalkylaryl, alkylcarbonyl, (per)fluororalkylcarbonyl, (per)fluoroalkylarylcarbonyl, and (per)fluoroalkylheteroarylcarbonyl each of which may be substituted by at least one substituent; and

n is same or different at each occurrence and is an integer from 1 to 4.

Another object of the present invention relates to the use of the above light emitting material and to provide an organic light emitting device including the above light emitting material.

Thus, the present invention provides a light emitting material, in which the

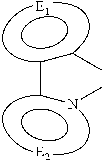

ligand is selected from phenylpyridine ligands substituted by at least one fluorine atom in the phenyl ring.

In some embodiments of the present invention, the phenylpyridine ligand is selected from the group consisting of:

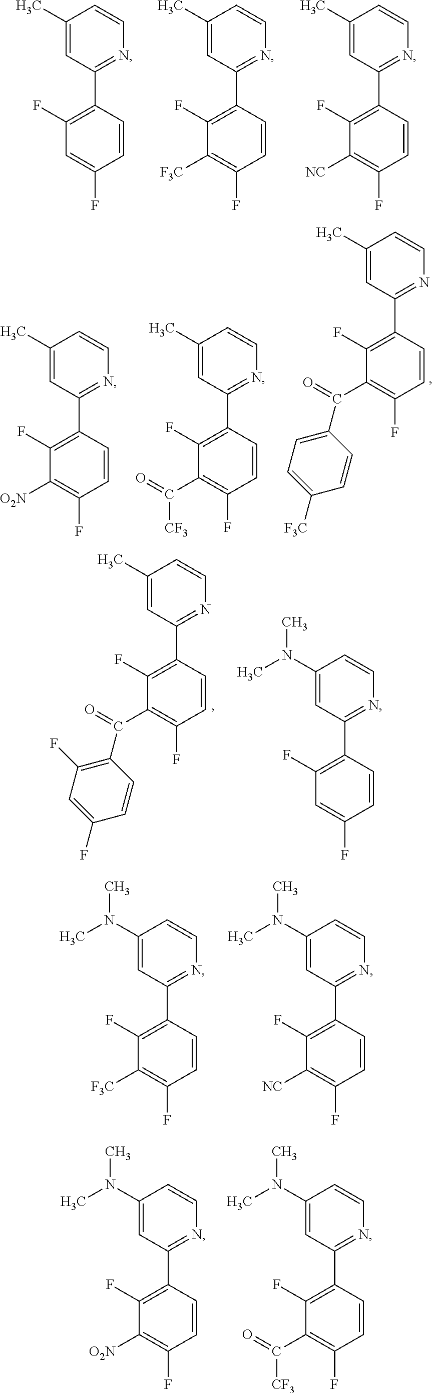

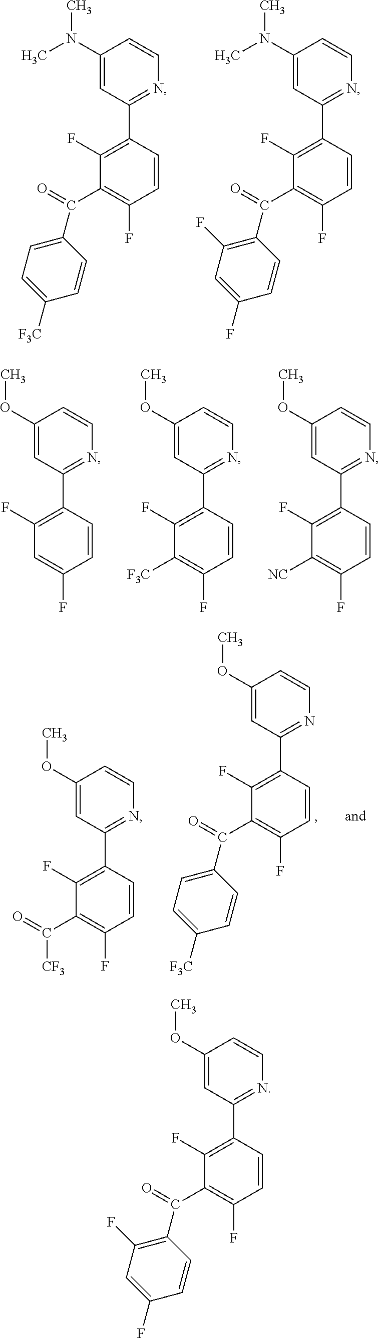

In other embodiments of the present invention, R₁ is independently selected from alkyl, dialkylamino and alkoxy groups. Specifically, R₁ is methyl or methoxy group. In such embodiments, n is 1.

In some embodiments of the present invention, R₂ is trifluoroalkyl, and more specifically trifluoromethyl group.

In specific embodiments of the present invention, the Ir complex has a formula selected from the group consisting of:

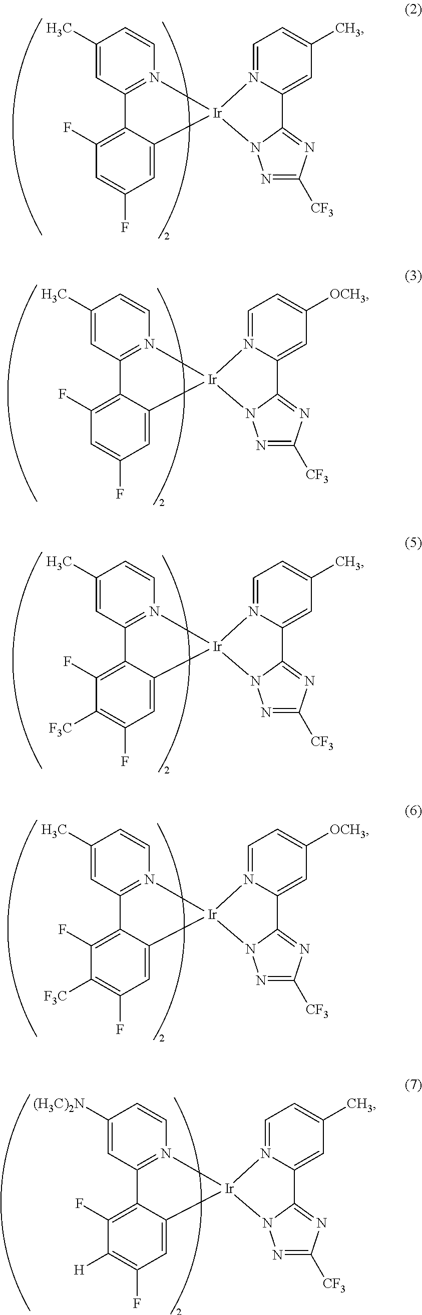

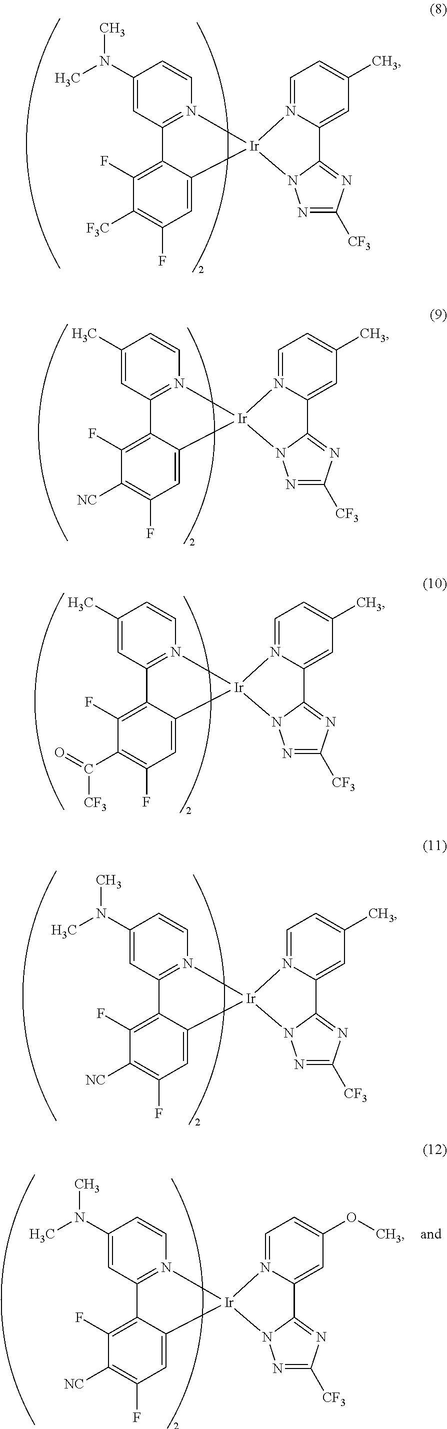

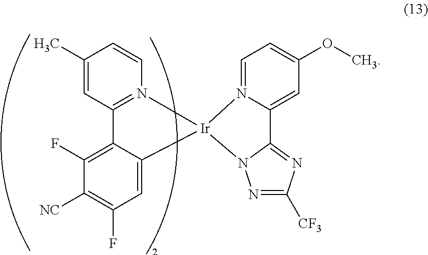

Surprisingly, it has been found that when an Ir complex has a pyridyl triazole ligand substituted with at least one substituent, the photoluminescence quantum yield (PQY) of the emitting material for specifically improving the efficiency of a device is significantly enhanced over other Ir complexes with a phenyl pyridine ligand having no substituent in its pyridine ring.

Generally, according to the first embodiment of the present invention, the Ir complexes having Formulae (2), (3) and (5) to (7) are prepared by reacting a dimer) ([ĈN]₂Ir(μ-X°)₂Ir[ĈN]₂) comprising two Ir atoms, two phenyl pyridine ligands (ĈN) and two halogen ligands)(X°) in the presence of a base compound with a substituted pyridyl triazole. The phenyl pyridine and substituted pyridyl triazole ligands are commercially available or can be easily synthesized by using well-known organic synthetic methods.

In particular, phenyl pyridine ligands can be prepared with good to excellent yields by Suzuki coupling the substituted pyridine compound with corresponding arylboronic acids in the presence of alkali metallic base such as potassium bicarbonate, as described in Lohse et al., “The Palladium Catalyzed Suzuki Coupling of 2- and 4-Chloropyridines,” Syn. Lett., 1:15-18 (1999) and U.S. Pat. No. 6,670,645 assigned to Dupont de Nemours.

[ĈN]₂Ir(μ-X°)₂Ir[ĈN]₂ complexes, wherein X° is halogen (e.g., Cl), can be prepared by using procedures already described in, for example, the following references: Sprouse et al., J. Am. Chem. Soc., 106:6647-6653 (1984); Thompson et al., Inorg. Chem., 40(7):1704 (2001); and Thompson et al., J. Am. Chem. Soc., 123(18): 4304-4312 (2001).

In some embodiments, the reaction is carried out by using an excess of the neutral form of the orthometalated ligand (H—ĈN) and high-boiling temperature solvents. The term “high-boiling temperature solvent” is intended to denote a solvent having a boiling point of at least 80° C., at least 85° C. or at least 90° C. For example, suitable solvents may be methoxyethanol, ethoxyethanol, glycerol, dimethylformamide (DMF), N-methylpyrrolidone (NMP), dimethylsulfoxide (DMSO) and the like, wherein the solvents can be used as is or in admixture with water.

Optionally, the reaction can be carried out in the presence of a suitable Brønsted base such as metal carbonates (e.g., potassium carbonate (K₂CO₃)), metal hydrides (e.g., sodium hydride (NaH)), metal ethoxide or metal methoxide (e.g., NaOCH₃ and NaOC₂H₅), alkylammonium hydroxides (e.g., tetramethylammonium hydroxide) or imidazolium hydroxides.

A nucleophilic substitution at the metal atom with a pyridyl triazole ligand may be carried out in the presence of a base compound by more or less contacting a stoichiometric amount of the pyridyl triazole ligand with a bridged intermediate in a suitable solvent.

The present invention is also directed to the use of a light emitting material in the emitting layer of an organic light emitting device (OLED).

Furthermore, the present invention relates to using the light emitting material including the Ir complexes, as described above, as a dopant in a host layer under conditions effective to function as an emissive layer in an organic light emitting device.

The present invention also relates to an OLED including an emissive layer. The emissive layer includes the light emitting material, as described above, optionally with a host material (wherein the light emitting material is specifically present as a dopant). The host material is notably adapted to luminesce when a voltage is applied across the device structure.

As depicted in FIG. 1, the OLED devices of the present invention comprises: a substrate (1); an anode (2); optionally a hole transporting layer (HTL, 3); an emissive layer (EML, 4); optionally a hole blocking layer (HBL, 5) and/or an electron transporting layer (ETL, 6); and a cathode (7). Such devices can be prepared by any method known in the art, e.g., U.S. Pat. No. 7,329,898 B1 assigned to Fujifilm Corp and WO/2008/043815 assigned to Solvay (Societe Anonyme).

Another aspect of the present invention relates to a display device including the above OLED.

### DESCRIPTION OF DRAWINGS

FIG. 1 is a cross-sectional view of a display device having an organic light emitting device of the present invention.

FIGS. 2-8 show absorption and phosphorescence spectra of the complexes of Formulae (1) to (7).

FIGS. 9a-9f show cyclic voltammograms of the complexes of Formulae (1) to (5) and (7).

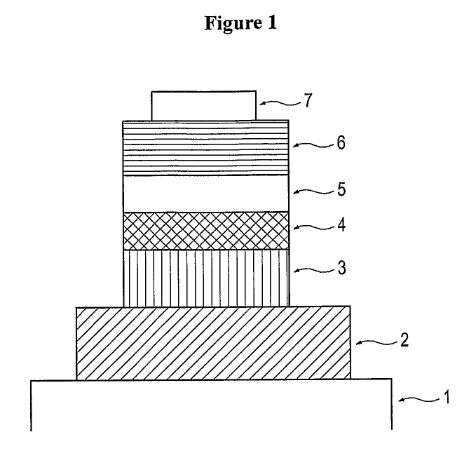

### BEST MODE

The Ir complex of the present invention is represented by formula (I) of:

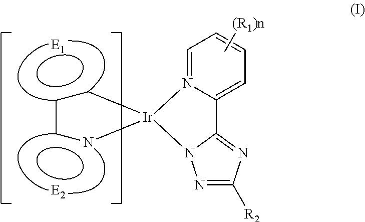

wherein:

E₁, E₂, R₁, R₂, and n are as previously defined herein.

### MODE FOR INVENTION

### Examples

Hereinafter, the present invention will be explained in detail with reference to examples and comparative examples. These examples, however, should not in any sense be interpreted as limiting the scope of the present invention. Further, units are expressed by weight unless otherwise described.

### Example 1

### Experimental Section

Chemical reagents have been purchased from Aldrich Chemical Co. and were used without further purification. Tetrahedrofuran (THF) was distilled over sodium in the presence of benzophenone. ¹H-NMR and ¹³C-NMR spectra were taken on the Varian Mercury 300 MHz spectrometer on CDCl₃ or CD₃OD solutions. All chemical shifts are reported in parts per million (d) relative to residual CHCl₃ at 7.26 ppm (for ¹H-NMR) and 77.0 ppm (for ¹³C-NMR) or CH₃OH at 4.78 (s), 3.30 (q) ppm (for ¹H-NMR) and 49.0 (septet) ppm (for ¹³C-NMR). The following abbreviations are used to denote signal patterns: s=singlet; d=doublet; t=triplet; q=quintet; br=broad; and m=multiplet. Analytical thin layer chromatography (TLC) was conducted using Merck 0.25 mm silica gel 60F precoated aluminium plates with fluorescent indicator UV254.

### Example 2

### Synthesis of Pyridyltriazole Ancillary Ligands (21, 22 and 23)

The pyridyl triazole-based ligand (i.e., compounds 21, 22 and 23) can be prepared by the following reaction scheme.

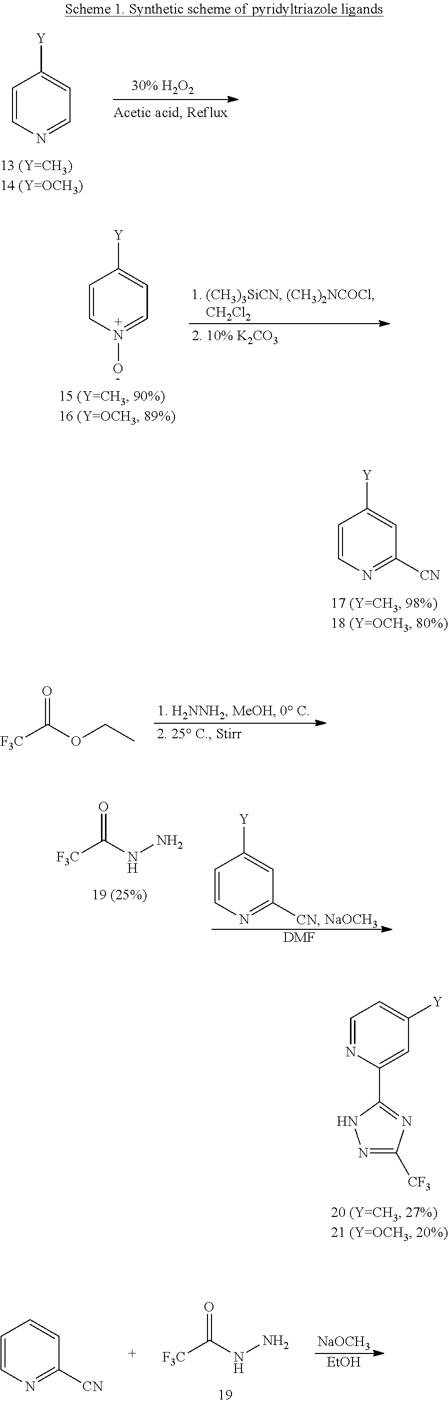

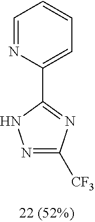

### 2-1. Preparation of 4-Methylpyridine N-Oxide (16)

4-Methylpyridine (3.0 ml, 30.0 mmol) was dissolved in glacial acetic acid (20.0 ml), 30% hydrogen peroxide (2.9 ml, 30.0 mmol) was added, and the reaction mixture was refluxed for 24 h. The reaction mixture was concentrated in vacuo and the resulting bright red solid, 16 (3.0 g, 27.0 mmol, 90%), was used without purification.

### 2-2. Preparation of 4-Methoxypyridine N-Oxide (17)

4-Methoxylpyridine (10.0 ml, 85.9 mmol) was dissolved in glacial acetic acid (50.0 ml), 30% hydrogen peroxide (8.4 ml, 85.9 mmol) was added, and the reaction mixture was refluxed for 24 h. The reaction mixture was concentrated in vacuo and the resulting red gummy liquid, 17 (9.6 g, 76.5 mmol, 89%), was used without further purification.

### 2-3. Preparation of 2-Cyano-4-methylpyridine (18)

4-Methylpyridine N-Oxide, 16 (1.32 g, 12.1 mmol), was dissolved in distilled dichloromethane (10.7 ml) and added to trimethylsilyl cyanide (1.8 ml, 13.6 mmol) at room temperature. Dimethylcarbamyl chloride (1.2 ml, 13.6 mmol) in dichloromethane (5.8 ml) was added dropwise with stirring to the reaction mixture. The reaction mixture was stirred at room temperature for 24 h. A solution of 10% aqueous potassium carbonate (20 ml) was added and stirring was continued for 30 min. The organic layer was separated and aqueous layer was extracted with dichloromethane. The combined organic layers were dried over anhydrous Na₂SO₄ and concentrated in vacuo. The crude product was purified by column chromatography on silica gel (solvent; dichloromethane). The desired 2-cyano-4-methylpyridine, 18 (1.4 g, 11.6 mmol, 96%), was obtained as a white solid.

### 2-4. Preparation of 2-Cyano-4-methoxylpyridine (19)

4-Methoxylpyridine N-Oxide, 17 (12.8 g, 0.1 mol), was dissolved in distilled dichloromethane (130 ml) and added to trimethylsilyl cyanide (16.0 ml, 0.1 mmol) at room temperature. Dimethylcarbamyl chloride (11.0 ml, 0.1 mmol) in dichloromethane (20.0 ml) was added dropwise with stirring to the reaction mixture. The reaction mixture was stirred at room temperature for 24 h. A solution of 10% aqueous potassium carbonate (100.0 ml) was added and stirring was continued for 30 min. The organic layer was separated and aqueous layer was extracted with dichloromethane. The combined organic layers were dried over anhydrous Na₂SO₄ and concentrated in vacuo. The crude product was purified by column chromatography on silica gel (ethyl acetate:n-hexane=1:6). The desired 2-cyano-4-methoxylpyridine, 19 (10.7 g, 80.1 mmol, 80%), was obtained as a white solid.

### 2-5. Preparation of Trifluoroacetyl hydrazide (20)

Ethyl trifluoroacetate (9.0 ml, 80.0 mmol) in methanol (8.0 mL) was stirred at 0° C. while hydrazine (90.0 ml, 0.1 mol, 1.0M solution in THF) was added. After 13 h, dichloromethane (100.0 ml) was added at room temperature and concentrated in vacuo. After evaporating the solvent, dichloromethane (60.0 ml) was added and the mixture was stirred at room temperature to product an insoluble white solid. The solid was removed and the solution was concentrated in vacuo and white gummy liquid, 20 (6.83 g, 53.3 mmol, 67%), was obtained.

### 2-6. Preparation of 3-Trifluoromethyl-5-(4-methyl-2-pyridyl)-1,2,4-triazole (21)

2-Cyano-4-methylpyridine, 18 (1.3 g, 9.3 mmol), in N,N-dimethyl formamide (60.0 ml) was added to 20 (2.2 g, 17.2 mmol) and stirred at room temperature. After 30 min, 28% NaOCH₃ solution in methanol (0.2 g) was added to the reaction mixture and refluxed at 153° C. for 2 days. The solution was evaporated in vacuo and water (50 ml) was added to the residue. This solution was extracted with ethyl acetate (50 ml×2). The organic solution was dried over sodium sulfate and the filtrate was evaporated in vacuo. The crude product was subjected to column chromatography on silica (solvent: ethyl acetate/chloroform=1/5) and white solid, 21 (0.6 g, 2.5 mmol, 27%), was obtained.

¹H-NMR (CDCl₃) δ 8.70 (d, 1H, J=5.4 Hz), 8.21 (s, 1H), 7.36 (s, 1H, J=5.4 Hz), 2.51 (s, 3H), ¹³C-NMR (CDCl₃) δ 21.1, 117.2, 120.8, 123.6, 126.9, 149.1, 150.6, 155.1, HRMS (M⁺, 229.0703, Calcd, 229.0623).

### 2-7. Preparation of 3-Trifluoromethyl-5-(4-methoxy-2-pyridyl)-1,2,4-triazole (22)

2-Cyano-4-methoxypyridine, 19 (2.0 g, 15.0 mmol), in N,N-dimethyl formamide (50.0 ml) was added to 20 (2.5 g, 19.5 mmol) and stirred at room temperature. After 30 min, 28% NaOCH₃ solution in methanol (1.4 g) was added to reaction mixture and refluxed at 153° C. for 3 days. The solution was evaporated in vacuo and water (40 ml) was added to the residue. This solution was extracted with ethyl acetate (40 ml×2). The organic solution was dried over sodium sulfate and the filtrate was evaporated in vacuo. The crude product was subjected to column chromatography on silica (solvent: ethyl acetate/chloroform=1/5) and colorless liquid, 22 (0.7 g, 3.0 mmol, 20%), was obtained.

¹H-NMR (CDCl₃) δ8.18 (d, 1H, J=6.3 Hz), 7.32 (s, 1H), 6.78 (s, 1H, J=6.3 Hz), 4.24 (s, 3H), ¹³C-NMR (CDCl₃) 39.0, 113.4, 113.8, 114.7, 117.0, 120.6, 124.1, 143.2, 146.7, 151.2, 151.7, 151.8, 152.2, 152.8, 170.0, HRMS (M⁺, 244.05, Calcd, 244.06).

### 2-8. Preparation of 3-Trifluoromethyl-5-(2-pyridyl)-1,2,4-triazole (23)

2-Cyanopyridine (0.93 ml, 9.6 mmol), purchased from Aldrich, in ethanol (30.0 ml) was added to 20 (2.5 g, 19.5 mmol) and stirred at room temperature. After 30 min, 28% NaOCH₃ solution in methanol (1.4 g) was added to reaction mixture and refluxed. After 2 h, ethanol was removed in vacuo and the remaining yellow gummy liquid was heated at 130° C. overnight. Water was added to the reaction mixture and the mixture was extracted with chloroform. The organic layer was dried over sodium sulfate and the filtrate was evaporated in vacuo. The crude product was subjected to column chromatography on silica (solvent: ethyl acetate/chloroform=1/5) and yellow solid, 23 (1.06 g, 5.0 mmol, 52%), was obtained.

¹H-NMR (CDCl₃) δ 8.84 (d, J=5.1 Hz, 1H), 8.35 (d, J=8.1 Hz, 1H), 8.01-7.95 (m, 1H), 7.57-7.52 (m, 1H)

### Example 3

### Synthesis of Main Ligand, 2-Phenylpyridines (24, 26 and 28)

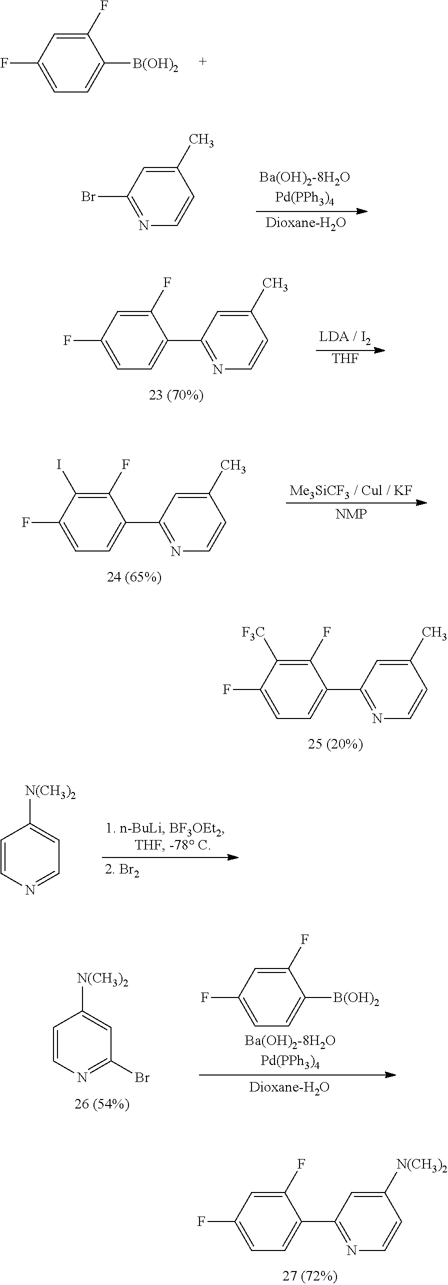

### 3-1. Synthesis of 2-(2′,4′-Difluorophenyl)-4-picoline (24)

2,4-Difluorophenyl boronic acid (1.1 g, 7.0 mmol), Ba(OH)₂.8H₂O (6.2 g, 19.5 mmol) and Pd(PPh₃)₄ (0.2 g, 0.3 mmol) were placed in a 100 mL one-neck round bottom flask equipped with a condenser. The flask was evacuated and filled with N₂ gas. 1,4-Dioxane (20.0 ml), H₂O (7.0 ml) and 2-bromo-4-picoline (1.2 g, 7.0 mmol) were added. The reaction mixture was refluxed for 30 h under N₂ gas and cooled to room temperature. The solvent dioxane was removed by evaporation and the contents were poured into a dichloromethane (30 ml). The precipitate was removed through filter paper and the organic layer washed with 1M NaOH (30 ml×2) and saturated aqueous NaCl (30 ml). It was then dried over sodium sulfate. After evaporation of the solvent, purification of the product by column chromatography (solvent: ethyl acetate/hexane=1/6) provided 2-(2′,4′-difluorophenyl)-4-picoline, 24 (1.0 g, 4.9 mmol, 70%), as the oil.

¹H-NMR (CDCl₃) δ8.56 (d, J=4.8 Hz, 1H), 7.92-8.00 (m, 1H), 7.53-7.59 (m, 1H), 7.08 (d, J=5.3 Hz, 1H), 6.96-7.02 (m, 1H), 6.87-6.95 (m, 1H), 2.41 (s, 3H)

### 3-2. Synthesis of 2-(2′,4′-Difluoro-3′-iodophenyl)-4-picoline (25)

2.0M Solution (12.5 ml, 25.0 mmol) of lithium diisopropyl amide in heptane/THF/ethylbenzene was added dropwise to the THF (43.0 ml) solution of 24 (3.5 g, 10.6 mmol) at −78° C. and stirred for 1 h. Then, iodine (6.1 g, 24 mmol) dissolved in THF (35 ml) was added to the solution. The mixture was stirred for 3 h at −78° C. and warmed to room temperature. Then, water (300 ml) was added and the solution was extracted with diethyl ether twice (100 ml×2). The ether solution was washed with water (100 ml), a saturated aqueous solution of Na₂S₂O₃ (100 ml) and a saturated aqueous solution of NaCl (100 mL). The solution was dried over sodium sulfate and the filtrate was evaporated in vacuo. The residue was subjected to column chromatography on silica gel (solvent: ethyl acetate/hexane=1/6). The desired 2-(2′,4′-difluoro-3′-iodophenyl)-4-picoline, 25 (5.4 g, 16.3 mmol, 65%), was obtained as a beige solid.

### 3-3. Synthesis of 2-[2′,4′-Difluoro-3′-(trifluoromethyl)phenyl]-4-picoline (26)

A mixture of copper (I) iodide (1.7 g, 9.1 mmol) and spray-dried anhydrous potassium fluoride (0.5 g, 9.1 g) was heated with a heat gun under reduced pressure while being gently shaken until the color changed into yellow. After the addition of 25 (2.0 g, 6.0 mmol), a vessel was Ar-purged and N-methylpyrrolidinone (10 ml) and (trifluoromethyl)trimethylsilane (1.8 ml, 12.1 mmol) were added to the mixture. Then, the suspension was vigorously stirred for 24 h at room temperature. The mixture was poured into 28% aqueous ammonia (66 ml) and extracted with dichloromethane. The organic layer was washed with water, brine and dried over sodium sulfate. The filtrate was evaporated in vacuo. The residue was subjected to column chromatography on silica gel (solvent: ethyl acetate/hexane=1/6). The desired 2-[2′,4′-difluoro-3′-(trifluoromethyl)phenyl]-4-picoline, (26, 0.3 g, 1.2 mmol, 20%), was obtained as a white solid.

### 3-4. Synthesis of 2-Bromo-4-(dimethylamino)pyridine (27)

A solution of 2-(dimethylamino)ethanol (1.6 ml, 16 mmol) in hexane (10 ml) was cooled at 0° C. n-BuLi (20 ml, 32 mmol, 1.6M solution in hexane) was added dropwise under a nitrogen atmosphere. After 30 min at 0° C., 4-(dimethylamino)pyridine (1.0 g, 8.0 mmol) was added at once as a solid. After 1 h of stirring at 0° C., the reaction medium was cooled at −78° C. and a solution of CBr₄ (6.7 g, 20.2 mmol) in hexane (20 ml) was added dropwise (20 min). The temperature was then allowed to rise to 0° C. (1.5 h). Hydrolysis was performed at this temperature with H₂O (20 ml). The aqueous phase was first extracted with diethyl ether and then with dichloromethane. After drying (Na₂SO₄), filtration and evaporation of solvents, the crude product was purified by column chromatography (solvent: ethyl acetate/hexane=1/2) and brown gummy solid, 27 (0.9 g, 4.3 mmol, 54%) was obtained.

### 3-5. Synthesis of 2-(2′,4′-Difluorophenyl)-4-(dimethylamino)pyridine (28)

2,4-Difluorophenyl boronic acid (1.1 g, 6.9 mmol), Ba(OH)₂.8H₂O (6.5 g, 20.6 mmol) and Pd(PPh₃)₄ (0.4 g, 0.3 mmol) were placed in a 100 mL one-neck round bottom flask equipped with a condenser. The flask was evacuated and filled with N₂ gas. 1,4-Dioxane/H₂O=1/3 (34.3 ml) and 2-bromo-4-(dimethylamino)pyridine (1.2 g, 6.9 mmol) were added. The reaction mixture was refluxed for 30 h under N₂ gas and cooled to room temperature. The dioxane was removed by evaporation and the contents were poured into dichloromethane (30 ml), the precipitate was removed through filter paper, and the organic layer washed with saturated aqueous NaCl (30 ml), and dried over sodium sulfate. After evaporation of the solvent, purification of the product by column chromatography (solvent: ethyl acetate/hexane=1/2) provided 2-(2′,4′-difluorophenyl)-4-(dimethylamino)-pyridine (28, 1.2 g, 5.0 mmol, 72%), as the yellow oil.

### Example 4

### Synthesis of Ir(III)-m-chloro-bridged Dimer Complexes (29˜31)

A mixture of iridium(III) chloride trihydrate (83.0 mg, 0.2 mmol) and 2-(2′4′-difluorophenyl)-4-picoline, 24 (0.12 g, 0.6 mmol) in 2-ethoxyethanol/water (4 ml; 3/1) was refluxed under nitrogen for 18 h at 120° C. After cooling to room temperature, the mixture was evaporated in vacuo and water was added to residue. The mixture was extracted with dichloromethane and the organic layer was washed with water and brine, and dried over sodium sulfate. The filtrate was evaporated in vacuo to provide the crude Ir(III)-m-chloro-bridged dimer complex, 29. Other new complexes 30, 31 were also prepared from the corresponding 2-phenylpyridine ligands 26, 28 by the similar procedure.

### Example 5

### Synthesis of Iridium(III) Complexes (1)˜(7)

A mixture of the resulting dimer complex 29 (0.13 g, 0.11 mmol), 2-(4-methylpyridyl)triazole (19, 0.06 g, 0.26 mmol) as an ancillary ligand and sodium carbonate (160 mg) was heated at 135° C. in 2-ethoxyethanol (7 ml) for 24 h under nitrogen. After cooling to room temperature, the solution was evaporated in vacuo and water was added to the residue. The mixture was extracted with dichloromethane and the dichloromethane solution was dried over sodium sulfate. The filtrate was evaporated in vacuo. The crude product was subjected to column chromatography on silica gel (solvent: dichloromethane/hexane=1/10) and finally purified by recrystallization from dichloromethane/hexane to provide complex 2 as a yellow solid. Other new Iridium (III) complexes 1 and 3˜7 were also prepared from the corresponding ancillary ligands 5-(2-pyridyl)triazoles 21 and 23 by the similar procedure with the corresponding iridium chloro-bridged dimer 30˜31.

### 5-1. Synthesis of Iridium (III) Complex (1) (38%)

¹H-NMR (CDCl₃) δ 8.29 (d, J=5.4 Hz, 1H), 8.06 (s, 1H), 8.04 (s, 1H), 7.57-7.73 (m, 1H) 7.56 (d, J=5.4 Hz, 1H), 6.81 (d, J=4.8 Hz, 1H), 6.72 (d, J=4.8 Hz, 1H), 6.55-6.40 (m, 2 Hz), 5.79 (dd, J=8.4 Hz, 2.4 Hz, 1H), 5.69 (dd, J=8.4 Hz, 2.4 Hz, 1H), 2.51 (s, 6H)

### 5-2. Synthesis of Iridium (III) Complex (2) (45%)

¹H-NMR (CDCl₃) δ 8.12 (s, 1H), 8.07 (s, 1H), 8.025 (s, 1H) 7.55 (d, J=5.4 Hz, 1H), 7.53 (d, J=5.4 Hz, 1H), 7.00 (d, J=5.4 Hz, 1H), 6.79 (d, J=5.4 Hz, 1H), 6.70 (d, J=5.4 Hz, 1H), 6.52-6.36 (m, 2H), 5.78 (dd, J=8.4 Hz, 2.4 Hz, 1H), 5.70 (dd, J=8.4 Hz, 2.4 Hz, 1H), 2.48 (m, 9H), ¹³C-NMR (CDCl₃) δ21.2, 21.4, 21.5, 53.4, 97.9, 98.2, 114.0, 122.7, 123.2, 123.6, 124.0, 124.1, 126.2, 147.4, 148.8, 149.3, 149.6, 149.9, 150.3, 151.1, 152.2, 163.4, 163.8, 164.7 HRMS (M⁺, 828.15, Calcd, 828.14)

### 5-3. Synthesis of Iridium (III) Complex (3) (48%)

¹H-NMR (CDCl₃) δ 8.04 (s, 1H), 8.00 (s, 1H), 7.72 (d, J=2.4 Hz, 1H), 7.52 (d, J=6 Hz, 1H), 7.45 (d, J=6 Hz, 1H), 7.23 (d, J=6 Hz, 1H), 6.77?d, J=6 Hz, 1H), 6.70 (d, J=6 Hz, 1H), 6.69 (d, J=6 Hz, 1H), 6.49-6.33 (m, 2H), 5.75 (dd, J=8.4 Hz, 2.7 Hz, 1H), 5.68 (dd, J=8.4 Hz, 2.7 Hz, 1H), 3.92 (s, 3H), 2.46 (s, 6H), HRMS (M⁺, 844.13, Calcd, 844.14)

### 5-4. Synthesis of Iridium (III) Complex (4) (30%)

¹H-NMR (CDCl₃) δ 8.88 (d, J=5.4 Hz, 1H), 8.63 (s, 1H), 8.58 (s, 1H), 8.01-7.96 (m, 1H), 7.91-7.82 (m, 1H), 7.60 (d, J=5.4 Hz, 1H), 6.66 (d, J=4.8 Hz, 1H), 6.62 (d, J=4.8 Hz, 1H), 5.75-5.62 (m, 2 Hz), 2.47 (s, 6H)

### 5-5. Synthesis of Iridium (III) Complex (5) (51%)

¹H-NMR (CDCl₃) δ 8.14 (s, 2H), 8.10 (s, 1H), 7.53 (d, J=5.7 Hz, 2H), 7.28 (d, J=5.7 Hz, 1H), 7.08 (d, J=5.7 Hz, 1H), 6.90 (d, J=5.7 Hz, 1H), 6.82 (d, J=5.7 Hz, 1H), 5.89 (d, J=10.5 Hz, 1H), 5.79 (d, J=10.5 Hz, 1H), 2.52 (s, 6H), 2.49 (s, 3H), HRMS (M⁺, 964.12, Calcd, 964.12)

### 5-6. Synthesis of Iridium (III) Complex (7) (49%)

¹H-NMR (CDCl₃) δ 8.08 (s, 1H), 7.58 (d, J=5.7 Hz, 1H), 7.44 (s, 1H), 7.38 (s, 1H), 7.21 (d, J=6.9 Hz, 1H), 6.96 (d, J=5.7 Hz, 1H), 6.92 (d, J=6.9 Hz, 1H), 6.47-6.32 (m, 2), 6.16 (d, J=6.9 Hz, 2.7 Hz, 1H), 6.08 (d, J=6.9 Hz, 2.7 Hz, 1H), 5.91 (d, J=8.5 Hz, 2.7 Hz, 1H), 5.86 (d, J=8.5 Hz, 2.7 Hz, 1H), 3.06 (d, 12H), 2.43 (s, 3H), HRMS (M⁺, 886.1960, Calcd, 886.1954)

### Example 6

### Measurement of Absorbance and Photoluminescence

The absorption and photoluminescence (PL) spectra were measured using the JASCO V-570 UV-vis spectrometer and the Hitach F-4500 fluorescence spectrometer in dichloromethane, respectively, at room temperature. Phosphorescence quantum yields (Φₚ) were estimated by using a chloroform solution of tris-2-tolylpyridyl iridium complex Ir(tpy)₃ as a standard with a known value of Φₚ=0.45. Mass spectra were recorded by using electron impact ionization (EI) or fast atomic bombardment (FAB) techniques.

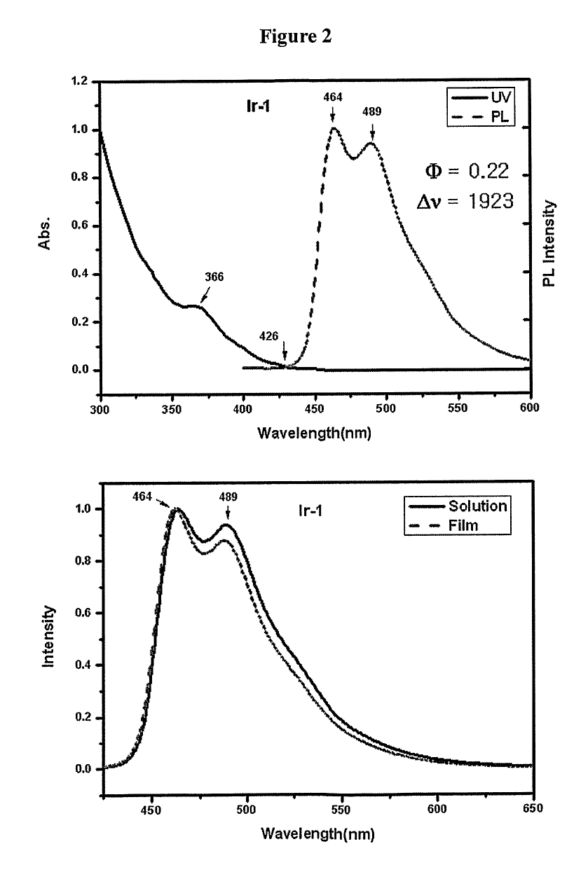

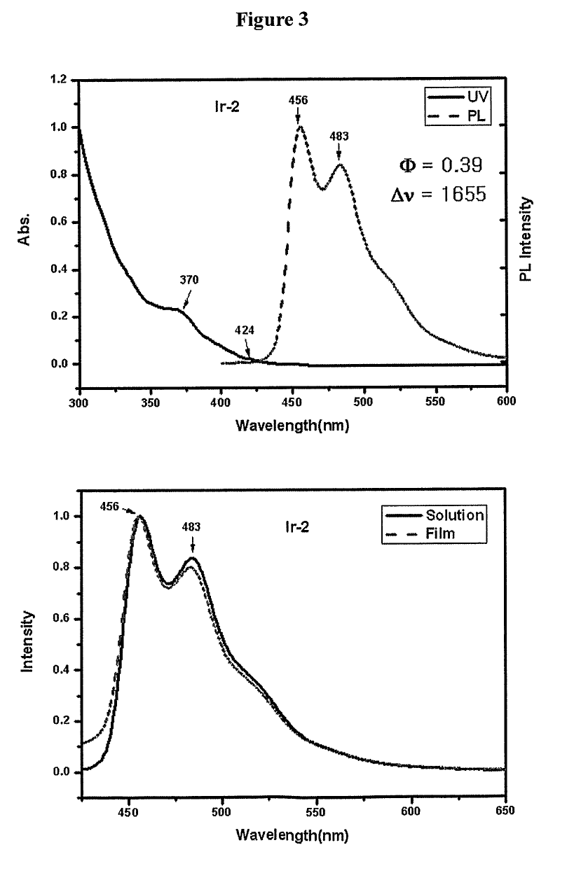

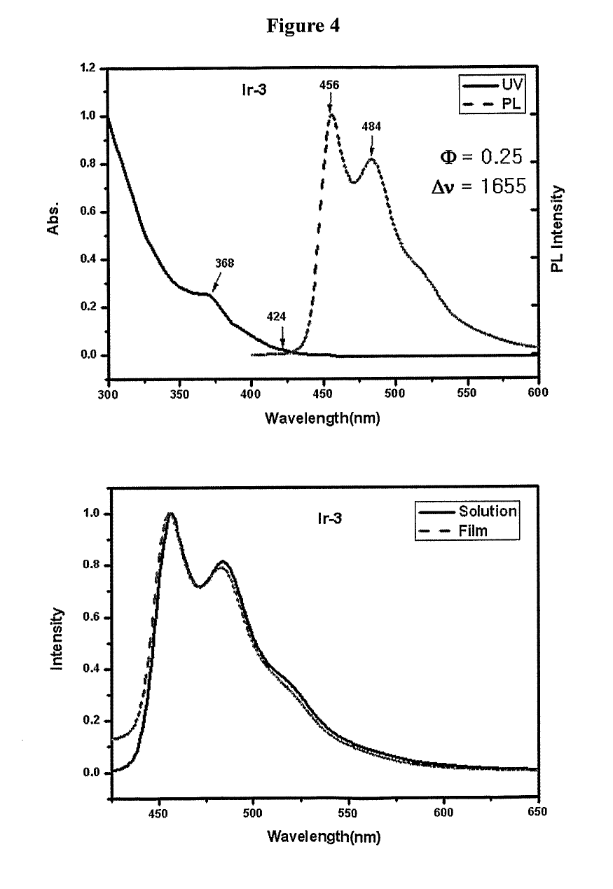

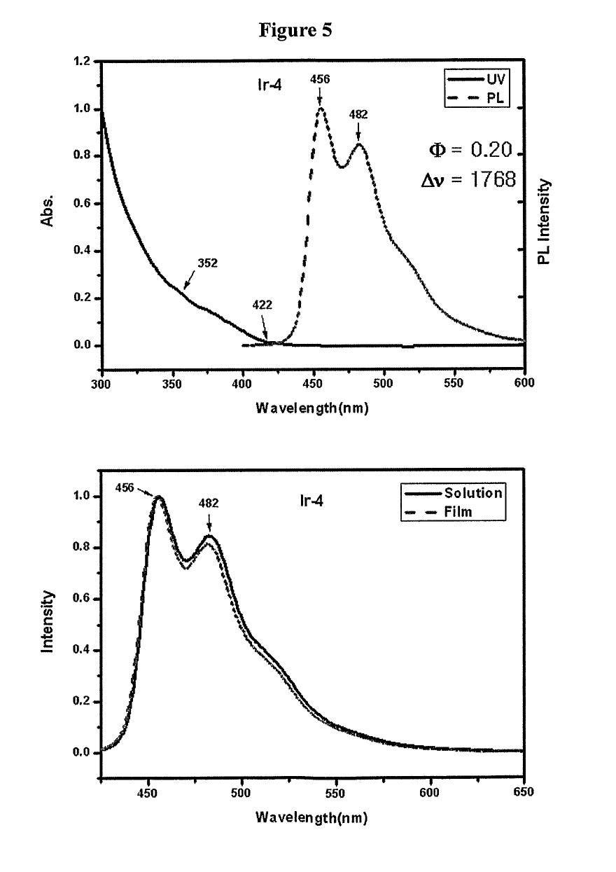

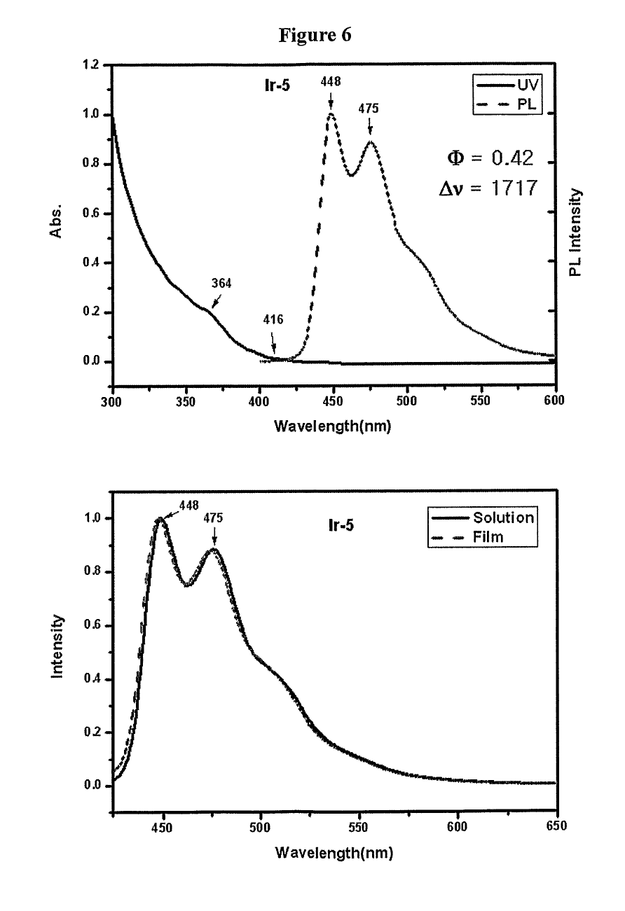

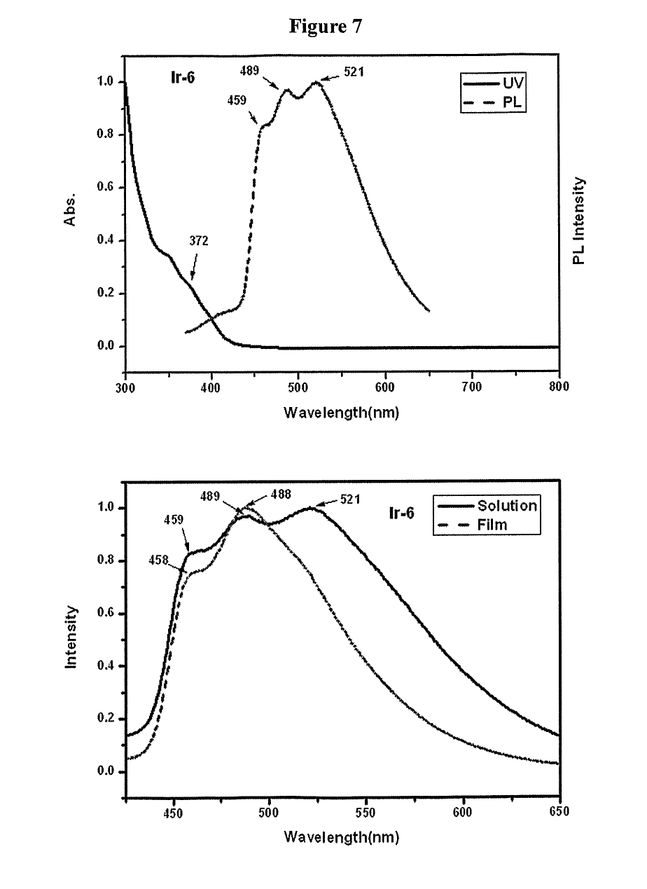

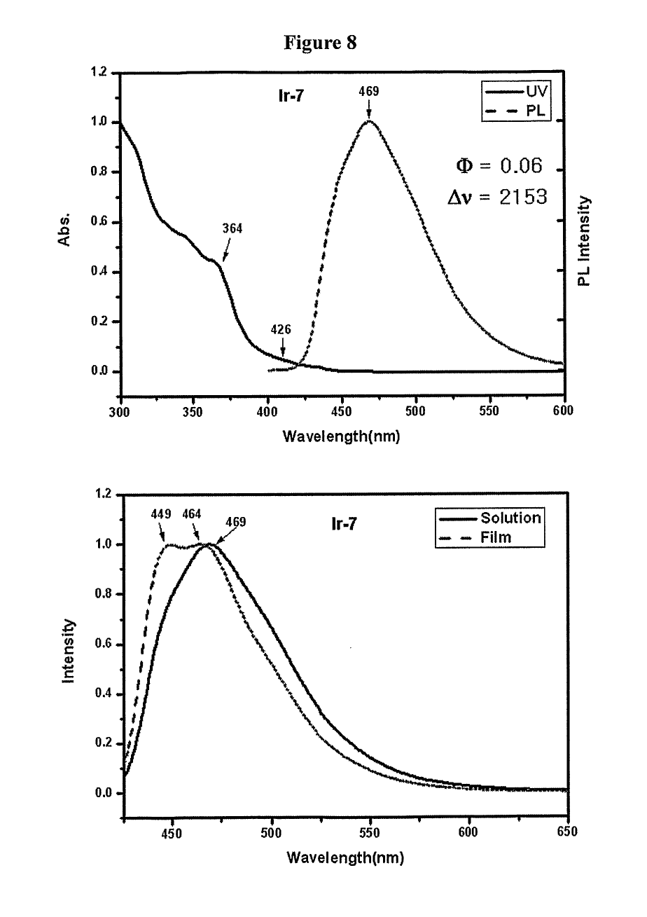

As shown in FIGS. 2-8 and Table 1, the Ir complexes of the present invention, i.e., compounds 2, 3, 5, and 7, exhibit higher quantum efficiency than compounds 1 and 4 having no substituent on the pyridyl ring of 5-pyridyltriazole ancillary ligand, as well as deeper blue emissions (more hypsochromic shift of the phosphorescent emission).

TABLE 1

| | MLCT | MLCT | | | Stokes shift | | | |
|---|---|---|---|---|---|---|---|---|
| Compound | (nm)^{(a)} | (nm)^{(a)} | λₑₘ (nm)^{(a)} | λₑₘ (nm)^{(b)} | (cm⁻¹) | E_{g}^{op (e)} | E_{g}^{op (f)} | Φₚ^{(c)} |
| 1 (Ir-1) | 366 | 426 | 464, 489 | 462, 489 | 1923 | 2.97 | 2.72 | 0.22 |
| 2 (Ir-2) | 370 | 424 | 456, 483 | 456, 483 | 1655 | 3.00 | 2.73 | 0.39 |
| 3 (Ir-3) | 368 | 424 | 456, 484 | 456, 483 | 1655 | 3.00 | 2.73 | 0.25 |
| 4 (Ir-4) | 352 | 422 | 456, 482 | 454, 481 | 1768 | 3.02 | 2.74 | 0.20 |
| 5 (Ir-5) | 364 | 416 | 448, 475 | 448, 475 | 1717 | 3.07 | 2.78 | 0.42 |
| 6 (Ir-6) | 372 | n.m. ^{(d)} | 459, 489, | 458, 488 | n.m. | 2.91 | ^{(d)} | n.m. |
| | | | 521 | | | | | |
| 7 (Ir-7) | 364 | 426 | 469 | 449,464 | 2153 | 3.07 | 2.72 | 0.06 |

^{(a)}2.7 × 10⁻⁴ ~ 1.3 × 10⁻³ M in dichloromethane;
^{(b)}A film state prepared by spin coating from dichloromethane solution with PMMA (5% w.t);
^{(c)}Phosphorescence quantum yields measured in dichloromethane solution using Ir(tpy)₃ (Φ = 0.45) as a reference; and
^{(d)} not measured.
^{(e)} Singlet optical band gap was calculated from singlet absorption edge
^{(f)} Triplet optical band gap was calculated from triplet absorption edge.

### Example 7

### Determination of HOMO and LUMO Levels

Electrochemical measurements were performed by using CHI600C(CH Instruments Inc., USA) with an electrochemical cell consisting of a platinum electrode (2 mm diameter), a Pt wire counter electrode and an Ag/AgCl reference electrode at RT. 0.1 M Tetrabutylammonium perchlorate (Bu₄NClO₄, TBAP) in dichloromethane (Aldrich, HPLC grade) was used as a supporting electrolyte (scan rate 50 m Vs⁻¹).

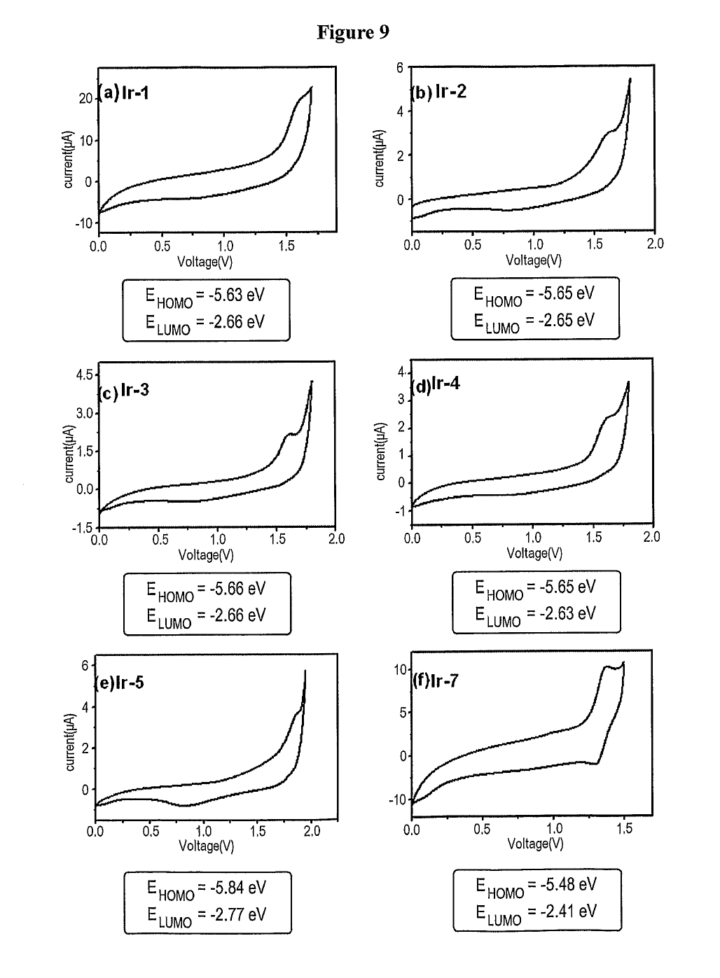

FIGS. 9a-9f show cyclic voltammograms of the Ir complexes of the present invention. The HOMO levels of Ir complexes (1) to (5) and (7) were determined as −5.63 eV, −5.65 eV, −5.66 eV, −5.65 eV, −5.84 eV and −5.48 eV, respectively, while the LUMO levels were −2.66 eV, −2.65 eV, −2.66 eV, −2.63 eV, −2.77 eV and −2.41 eV, respectively. An incorporation of methyl group at 4-position of pyridyl ring in 5-(2-pyridyl)triazole ancillary ligand, particularly for complex (5), resulted in a slight increase in band gap between the HOMO and LUMO levels.

### INDUSTRIAL APPLICABILITY

As described above, the iridium complexes of the present invention show the blue emission at 448 nm at the shortest and a great applicability for efficient blue OLED phosphorescent compound, while exhibiting very high phosphorescent quantum efficiencies. Such improved performance makes them promising compounds as emissive materials for blue emission.

It will be apparent to those skilled in the art that various modifications and variations can be made to the present invention without departing from the spirit and scope of the invention. Thus, it is intended that the present disclosure covers the modifications and variations of this invention, provided they come within the scope of the appended claims and their equivalents.

1. An Ir complex represented by formula (I): 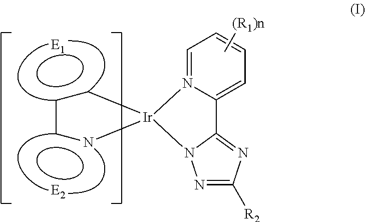
wherein:
E₁ represents an aromatic or heteroaromatic ring optionally condensed with additional aromatic moieties or non-aromatic cycles, said ring optionally having one or more substituents optionally forming a condensed structure with a ring comprising E₂, said ring coordinating to the metal M via a sp² hybridized carbon;
E₂ represents a N-containing aromatic ring optionally condensed with additional aromatic moieties or non-aromatic cycles, said ring optionally having one or more substituents optionally forming a condensed structure with the ring comprising E₁, said ring coordinating to the metal M via a sp² hybridized nitrogen;
R₁ is an electron-donating group which is same or different at each occurrence and is independently selected from the group consisting of —F, —Cl, —Br, a straight or branched C₁₋₂₀ alkyl, a C₃₋₂₀ cyclic alkyl, a straight or branched C₁₋₂₀ alkoxy, a C₁₋₂₀ dialkylamino, a C₄₋₁₄ aryl, a C₄₋₁₄ heteroaryl which may be substituted by one or more non-aromatic radicals; and a plurality of substituents R₁ either on the same ring or on two different rings forming a further mono- or polycyclic ring system which is optionally aromatic;
R₂ is an electron-withdrawing group which is selected from the group consisting of —F, —CN, NO₂, (per)fluoroalkyl, (per)fluoroaryl, (per)fluororalkylaryl, alkylcarbonyl, (per)fluororalkylcarbonyl, (per)fluoroalkylarylcarbonyl, and (per)fluoroalkylheteroarylcarbonyl each of which may be substituted by at least one substituent; and
n is same or different at each occurrence and is an integer from 1 to 4.

2. The Ir complex according to claim 1, wherein the 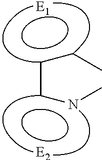
ligand is selected from the group consisting of phenylpyridine ligands substituted by at least one fluorine atom in the phenyl ring.

3. The Ir complex according to claim 2, wherein the phenylpyridine ligand is selected from the group consisting of

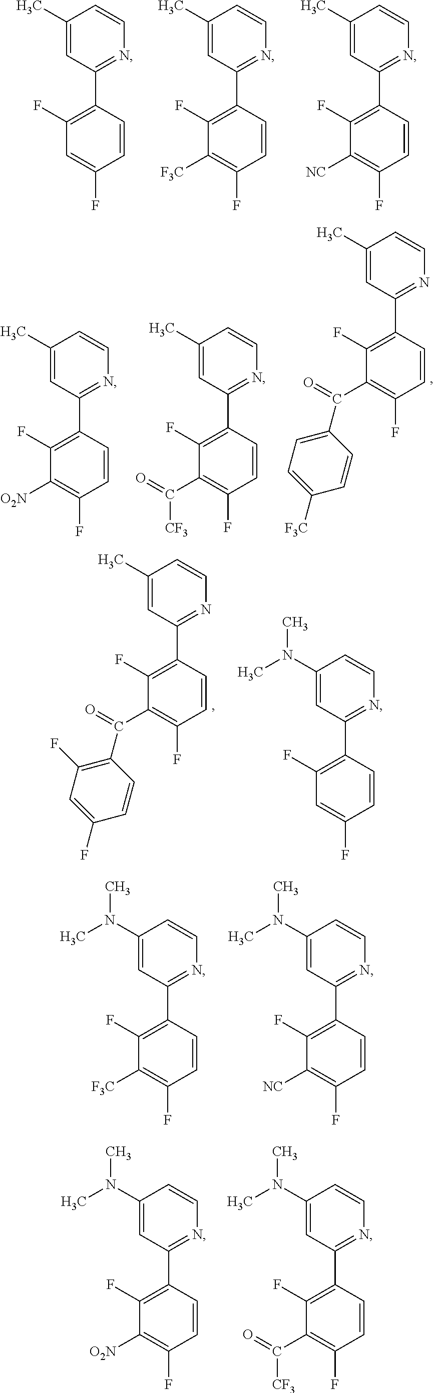

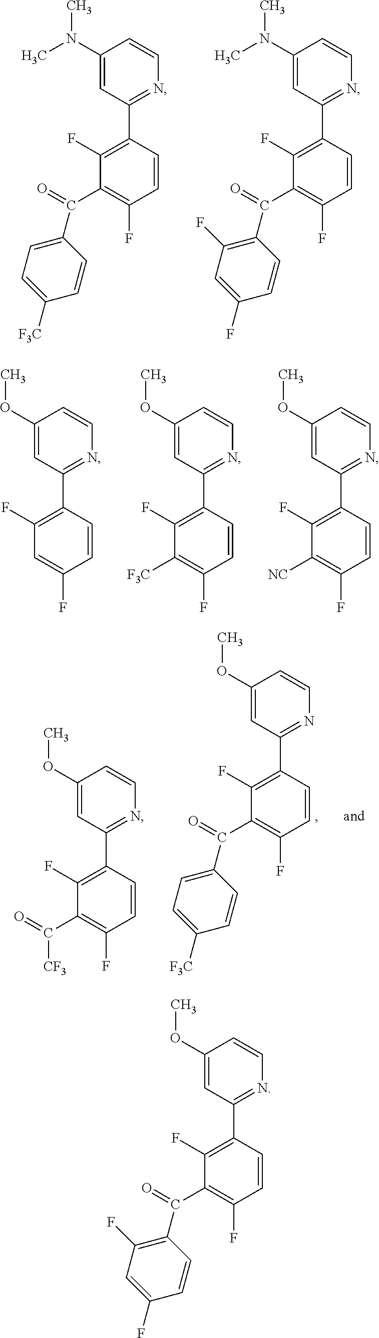

4. The Ir complex according to claim 1, wherein R₁ is independently selected from the group consisting of alkyl, dialkylamino, and alkoxy groups.

5. The Ir complex according to claim 1, wherein R₁ is methyl, and n is 1.

6. The Ir complex according to claim 1, wherein R₁ is dialkylamino, and n is 1.

7. The Ir complex according to claim 1, wherein R₁ is methoxy, and n is 1.

8. The Ir complex according to claim 1, wherein R₂ is trifluoromethyl.

9. The Ir complex according to claim 1, wherein said Ir complex has a formula selected from the group consisting of:

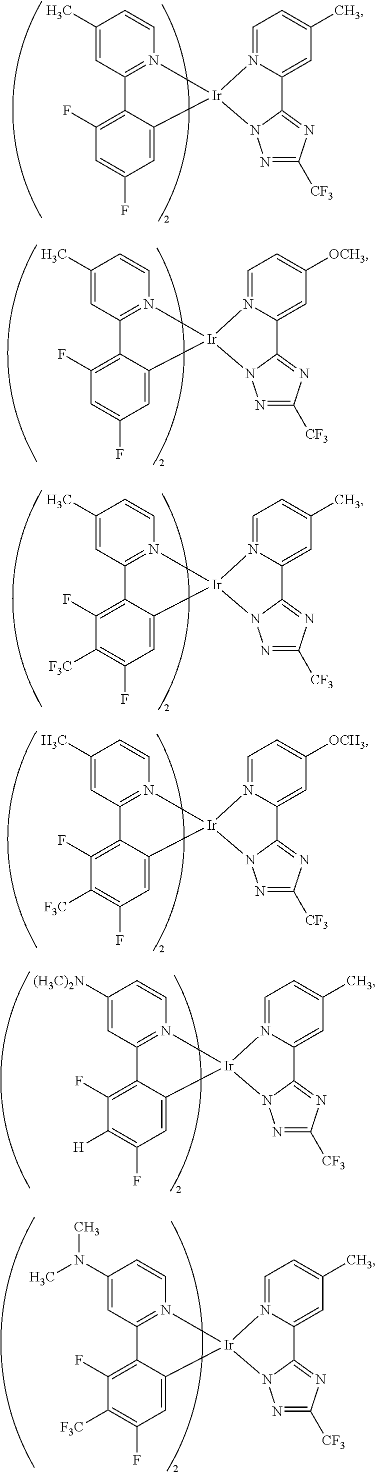

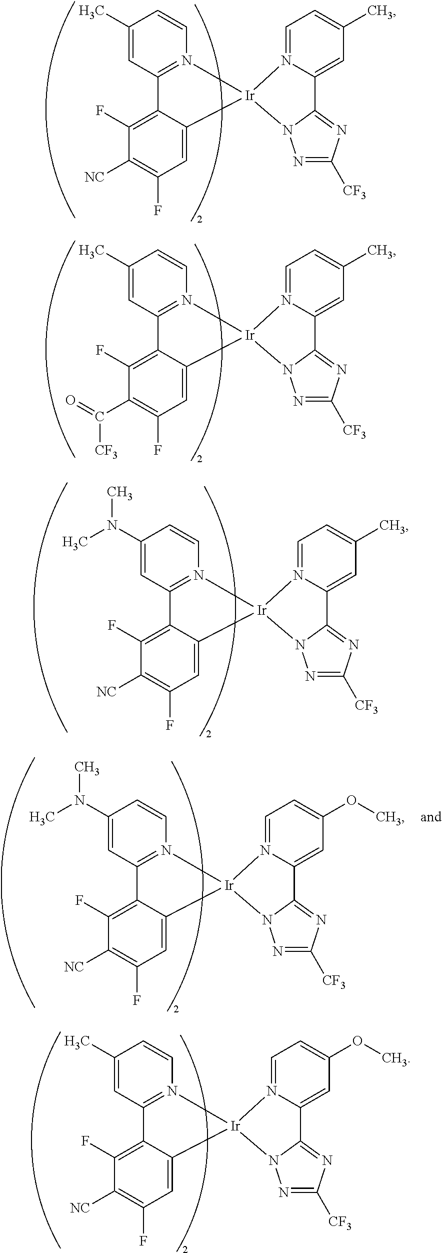

10. A light emitting material comprising the Ir complex according to claim 1.

11. A method for emitting light, comprising using the light emitting material according to claim 10 in an emissive layer of an organic light emitting device.

12. A method for emitting light, comprising using the light emitting material according to claim 10 as a dopant in a host layer under conditions effective to function as an emissive layer in an organic light emitting device.

13. An organic light emitting device comprising an emissive layer, wherein said emissive layer comprises the light emitting material according to claim 10 and optionally a host material.

14. A display device comprising the organic light emitting device according to claim 13.

15. The Ir complex according to claim 3, wherein R₁ is independently selected from the group consisting of alkyl, dialkylamino, and alkoxy groups.

16. The Ir complex according to claim 3, wherein R₂ is trifluoromethyl.

17. The Ir complex according to claim 15, wherein R₂ is trifluoromethyl.

18. The Ir complex according to claim 1, wherein R₂ is trifluoroalkyl.

19. The Ir complex according to claim 3, wherein R₂ is trifluoroalkyl.

20. The Ir complex according to claim 15, wherein R₂ is trifluoroalkyl.
